(19) United States
(12) Patent Application Publication
(10) Pub. No.: US 2007/0254476 A1
(43) Pub. Date: Nov. 1, 2007

(54) Cleaning porous low-k material in the formation of an interconnect structure

(75) Inventors: Chun-Li Chou, Jhubei City (TW); Jyu-Horng Shieh, Hsin-Chu (TW); Syun-Ming Jang, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/500,025

(22) Filed: Aug. 7, 2006

Related U.S. Application Data
(60) Provisional application No. 60/795,746, filed on Apr. 28, 2006.

(51) Int. Cl. H01L 21/4763

(52) U.S. Cl. 438/643; 438/906; 438/706; 134/2

(57) ABSTRACT

A cleaning solution and a method for cleaning a semiconductor wafer using the cleaning solution are provided. The method includes submerging the semiconductor wafer in a cleaning solution to remove by-products generated during integrated circuit formation processes. The cleaning solution includes an organic solvent, a metal reagent, a substitutive agent, and water.

This application claims the benefit of Provisional Patent Application Ser. No. 60/795,746, filed Apr. 28, 2006, and entitled “Cleaning Porous Low-k Material in the Formation of an Interconnect Structure,” which application is incorporated herein by reference.

### TECHNICAL FIELD

This invention relates generally to integrated circuits, and more particularly to the formation processes of interconnect structures with porous low-k dielectric materials.

### BACKGROUND

High-density integrated circuits, such as very large scale integration (VLSI) circuits, are typically formed with multiple metal interconnects to serve as three-dimensional wiring line structures. The purpose of multiple interconnects is to properly link densely packed devices together. With increasing levels of integration, a parasitic capacitance effect between the metal interconnects, which leads to RC delay and cross talk, increases correspondingly. In order to reduce the parasitic capacitance and increase the conduction speed between the metal interconnections, low-k dielectric materials are commonly employed to form inter-layer dielectric (ILD) layers and inter-metal dielectric (IMD) layers.

One of the commonly used schemes for forming low-k related structures is a metal hard mask (MHM) scheme, wherein a metallic hard mask is formed to protect a low-k dielectric layer from chemical mechanical polish (CMP). Typically, a cap layer or a bottom anti-reflective coating is formed on the low-k dielectric layer, followed by the formation of a metal hard mask layer. The metal hard mask layer and the cap layer are then patterned, preferably using photo resists as masks. The patterns are transferred to the underlying low-k dielectric layer to form interconnections, and the process typically includes forming openings in the low-k dielectric layer, filling the openings with a conductive material, and performing a CMP to planarize the surface. The metal hard mask layer is then removed.

The step of forming openings in the low-k dielectric layer generates certain by-products, including organic and inorganic by-products, which adversely affect the subsequent process steps and the reliability of the final integrated circuit. Conventionally, a multi-step cleaning process is performed to remove these by-products. The multi-step cleaning process is complex and typically includes both dry and wet cleaning steps. A simpler cleaning process is thus needed.

### SUMMARY OF THE INVENTION

In accordance with one aspect of the present invention, a cleaning solution for cleaning a semiconductor wafer is provided. The cleaning solution includes an organic solvent, a metal reagent, a substitutive agent, and water.

In accordance with another aspect of the present invention, a method for cleaning a semiconductor wafer includes submerging the semiconductor wafer in the cleaning solution to remove by-products generated in integrated circuit formation processes.

In accordance with yet another aspect of the present invention, a method for forming an interconnect structure of an integrated circuit includes forming a low-k dielectric layer over a substrate, forming a metal hard mask over the low-k dielectric layer, patterning the metal hard mask to forming a first opening in the metal hard mask wherein the low-k dielectric layer is exposed through the first opening, etching the low-k dielectric layer through the first opening to form a second opening in the low-k dielectric layer, performing a cleaning step by submerging the substrate and overlying structures in a cleaning solution, forming a diffusion barrier layer in the second opening, and filling the second opening with a conductive material. The cleaning solution preferably includes an organic solvent, a metal reagent, a substitutive agent, and water.

In a single step, the cleaning solution removes organic and inorganic by-products generated during the formation of the interconnect structure.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 9 are cross-sectional views of intermediate stages in the manufacture of a preferred embodiment of the present invention.

### DETAILED DESCRIPTION OF ILLUSTRATIVE EMBODIMENTS

The making and using of the presently embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

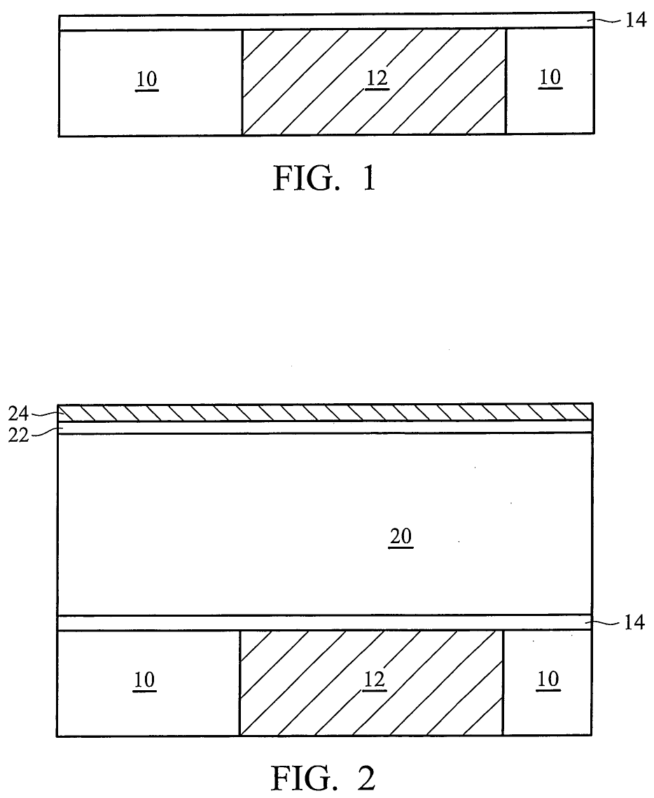

The embodiments of the present invention are illustrated in FIGS. 1 through 9, wherein like reference numbers are used to designate like elements throughout the various views and illustrative embodiments of the present invention.

Referring to FIG. 1, a metal line 12 is formed in a dielectric layer 10. Metal line 12 preferably comprises copper or copper alloys. A diffusion barrier layer (not shown) is preferably formed between metal line 12 and dielectric layer 10. An etch stop layer (ESL) 14 is formed on metal line 12 and dielectric layer 10. ESL 14 preferably comprises silicon nitride, silicon oxide, silicon carbide, silicon oxynitride, and/or other commonly used materials.

FIG. 2 illustrates the formation of a low-k dielectric layer 20 on ESL 14. Low-k dielectric layer 20 preferably has a dielectric constant (k value) lower than about 3.5, and more preferably lower than about 2.5, hence is sometimes referred to as an extreme low-k dielectric layer. Low-k dielectric layer 20 preferably comprises carbon-doped silicon oxides, fluorine-doped silicon oxides, and the like. The corresponding deposition methods include spin on, chemical vapor deposition (CVD), plasma enhanced CVD (PECVD), low pressure CVD (LPCVD), and other known deposition techniques.

A cap layer 22 is formed on low-k dielectric layer 20. Cap layer 22 is preferably nitrogen free, and preferably comprises materials such as carbon and oxygen. Cap layer 22 is also preferably used as a bottom anti-reflective coating (BARC), which is used for patterning the subsequently formed metal hard mask. Therefore, cap layer 22 is alternatively referred to as nitrogen-free anti-reflective coating (NFARC) 22. The preferred formation methods include chemical vapor deposition (CVD) and physical vapor deposition (PVD). However, other methods such as atomic layer deposition (ALD) may also be used.

A metal hard mask (MHM) 24 is formed on cap layer 22. MHM 24 is preferably formed of metallic materials, such as Ti, TiN, Ta, TaN, Al, and the like, although in a non-metal hard mask scheme, non-metallic materials such as SiO₂, SiC, SiN and SiON may be used.

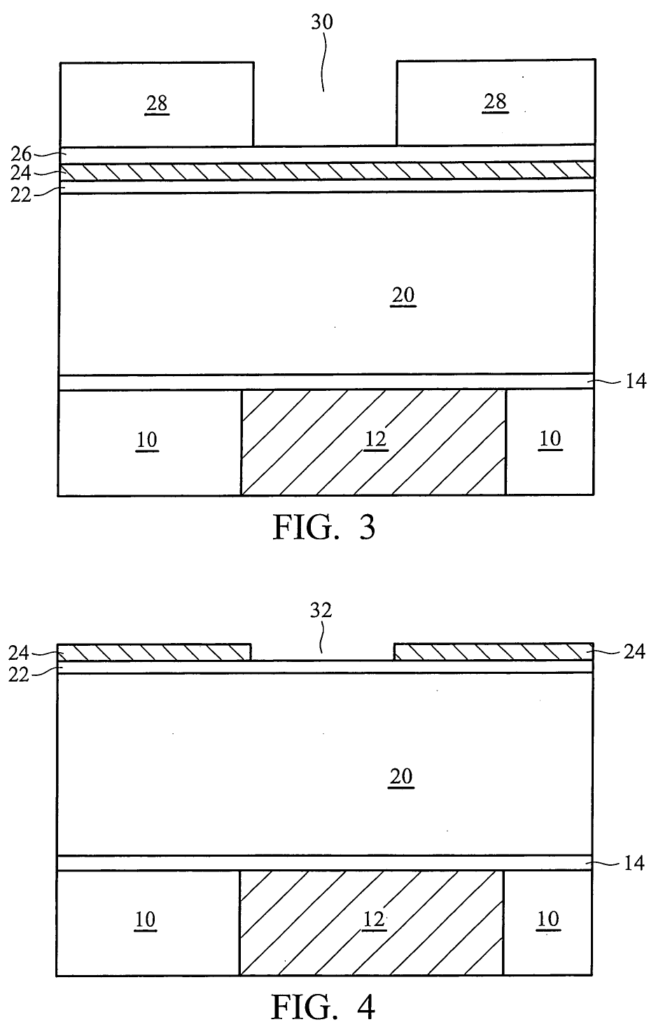

Referring to FIG. 3, an anti-reflective coating (ARC) 26 is formed over MHM 24. ARC 26 is also referred to as bottom anti-reflective coating (BARC) 26 since it is formed under a subsequently formed photo resist 28. Alternatively, a top anti-reflective coating (TARC) may be formed on top of the subsequently formed photo resist 28. BARC 26 absorbs light and provides ultimate critical dimension control. BARC 26 can be applied by spin on technique or can be deposited in a gas chamber.

Photo resist 28 is then formed and patterned, and an opening 30 is formed therein, exposing the underlying BARC 26. Next, an opening 32 is formed through MHM 24, as is illustrated in FIG. 4, by etching BARC 26 and MHM 24 through opening 30. Photo resist 28 and BARC 26 are then removed. In subsequent dual damascene processes, opening 32 is used to define a trench pattern for the metal line.

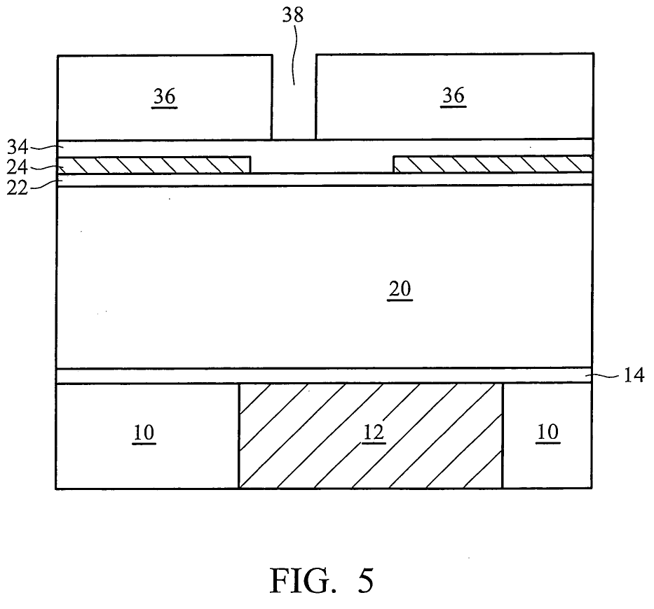

Referring to FIG. 5, a BARC 34 and a photo resist 36 are formed. Photo resist 36 is then patterned, forming an opening 38, which defines a pattern for a subsequently formed via.

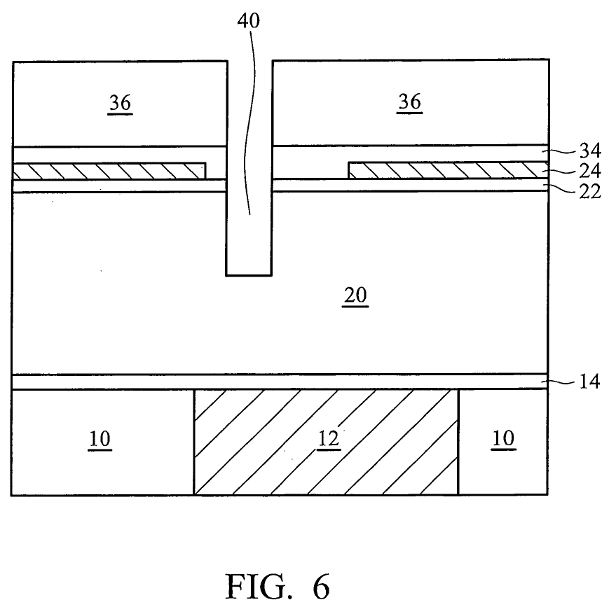

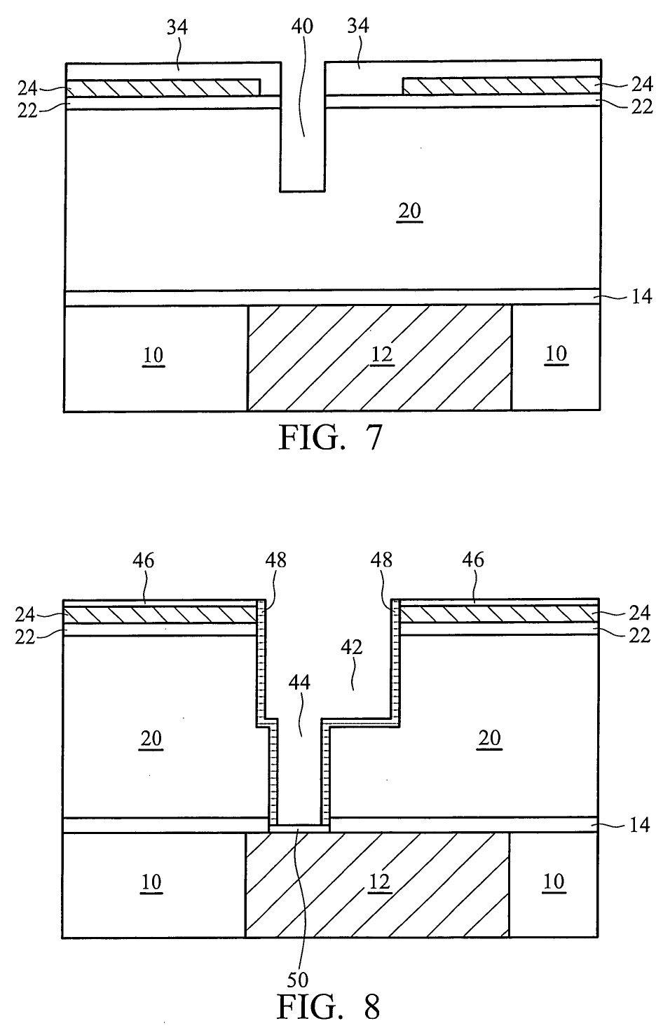

Next, a via partial etch is performed, as is illustrated in FIG. 6. Using photo resist 36 as a mask, underlying layers, including BARC 34, cap layer 22 and a portion of low-k dielectric layer 20, are removed, forming an opening 40 in low-k dielectric layer 20. The etching process is controlled so that the opening 40 has a desired depth, which is less than the thickness of low-k dielectric layer 20. The via partial etch is preferably performed using dry etching. In the preferred embodiment, plasma etching is used. An ashing process is then performed to remove photo resist 36, and the resulting structure is shown in FIG. 7.

FIG. 8 illustrates the formation of a trench opening 42 and a via opening 44, preferably by dry etching. In the preferred embodiment, plasma etching is used. The exemplary etching gases preferably include CF₄, C₄F₈, and the like. The etching process attacks BARC 34, cap layer 22 and low-k dielectric layer 20. As is known in the art, appropriate chemicals are preferably combined with process control so that the formation of trench opening 42 and via opening 44 can be performed at a controllable rate. During the etching process, opening 40 extends downward until low-k dielectric layer 20 is etched through, forming via opening 44. In the meantime, MHM 24 acts as a new mask, and the portion of low-k dielectric layer 20 unprotected by MHM 24 is etched. Since MHM 24 defines the pattern of the trench for a metal line, trench opening 42 is formed. With careful control of the etching process, trench opening 42 will reach a desired depth when via opening 44 reaches the bottom of low-k dielectric layer 20. A liner removal step is then performed to remove the exposed ESL 14 from via opening 44.

During the via partial etching, the etching of openings 42 and 44, and the liner removal step, by-products are formed. Typically, these by-products include both organic by-products and inorganic by-products, which are schematically illustrated in FIG. 8. For example, due to the plasma etching, the surface of MHM 24 is damaged, and a by-product layer, which is schematically illustrated as layer 46, is formed. In an exemplary embodiment wherein MHM 24 comprises titanium, layer 46 may include TiF. On sidewalls of trench opening 42 and via opening 44, a carbon organic layer 48 is formed as the result of etching the carbon-containing low-k dielectric layer 20. On the bottom of via opening 44, a by-product layer 50, which may contain CuO, CuF, and the like, is formed. It should be appreciated, however, that the previously discussed by-products and corresponding layers are merely examples, and may change depending on the materials of low-k dielectric layer 20, MHM 24, metal line 12, etching gases, etc. Any of the above-discussed by-products are likely to be in all layers 46, 48 and 50.

These by-products have adverse effects on subsequent processes. For example, TiF contaminates the formation of a subsequently formed diffusion barrier layer and copper filling. Carbon organic materials not only increase the k value of the interconnect structure, but also reduce its reliability. CuO and CuF increase the via resistance and affect its reliability also. Therefore, these by-products need to be removed.

In the preferred embodiment, a cleaning solution is used to remove the by-products by submerging the wafer on which the previously discussed structure is formed in the cleaning solution. The preferred temperature of the cleaning solution is between about 20° C. and about 70° C. The preferred cleaning time is less than about 8 minutes, and more preferably less than about 4 minutes. However, temperatures higher than about 70° C. or lower than about 20° C., and cleaning time greater than 8 minutes may also be used. One skilled in the art will be able to find an optimum time and temperature through routine experiments.

Preferably, the cleaning solution includes four components: an organic solvent for removing organic by-products, a metal reagent for removing inorganic by-products, a substitutive agent for controlling the cleaning process, and water (preferably de-ionized water). In the preferred embodiment, the cleaning solution includes from about 0.01% to about 90% weight percent organic solvent, about 0.01% to about 30% weight percent metal reagent, about 0.01% to about 30% weight percent substitutive agent, and about 0.01% to about 70% weight percent water. More preferably, the organic solvent is between about 50% weight percent and about 80% weight percent, and the metal reagent is between about 0.01% weight percent and about 10% weight percent. The substitutive agent is preferably between about 0.01% weight percent and about 10% weight percent, and water is less than about 50% weight percent.

The organic solvent preferably includes a material selected from propylene glycol monomethyl ether, ethylene glycol, 1,4-butynediol, butyrolactone, diethylene glycol monoethyl ether, diethylene glycol monobutyl ether, diethylene glycol monohexyl ether, N,N-dimethyl acetamide, N-methyl-2-pyrrolidone, cyclopentanone, dimethylsulfoxide, and combinations thereof.

The metal reagent preferably includes a material selected from oxalic acid, malonic acid, citric acid, lactic acid, glycolic acid, propionic acid, Benzotriazole, 1,2,4-1H-Triazole, 7-Methylindole-2-carboxylic acid, Thioglycerol, 1-pyrroline-5-carboxylate, Tetramethylammonium fluoride, 1,2-ethanedicarboxylic acid, Glyoxylic Acid, 1,2-ethanedicarboxylic acid, and combinations thereof.

The substitutive agent preferably includes a material selected from tetramethyl ammonium hydroxide, tetraethylammonium hydroxide, tetra-n-butylammonium hydroxide, 3-Aminopropanoic acid, 4-Aminobutyric acid, 6-Aminohexanoic acid, 5-Aminovaleric acid, and combinations thereof.

In one exemplary cleaning solution, the organic solvent includes about 60% to about 80% weight percent of dimethylsulfoxid and/or N-methyl-2-pyrrolidone, the metal reagent includes about 0.5% to about 2% weight percent of citric acid, thioglycerol, and/or 1,2,4-1H-Triazole, the substitutive agent includes about 0.5% to about 2% weight percent of tetramethyl ammonium hydroxide and/or tetra-n-butylammonium hydroxide, and about 25% weight percent of water. In another exemplary embodiment, the organic solvent includes about 60% to about 80% weight percent of dimethylsulfoxide and/or N-methyl-2-pyrrolidone, the metal reagent includes about 0.5% to about 2% weight percent of tetramethylammonium fluoride, thioglycerol and/or 1,2,4-1H-Triazole, the substitutive agent includes about 0.5% to about 2% weight percent of tetra-n-butylammonium hydroxide, and about 25% weight percent of water.

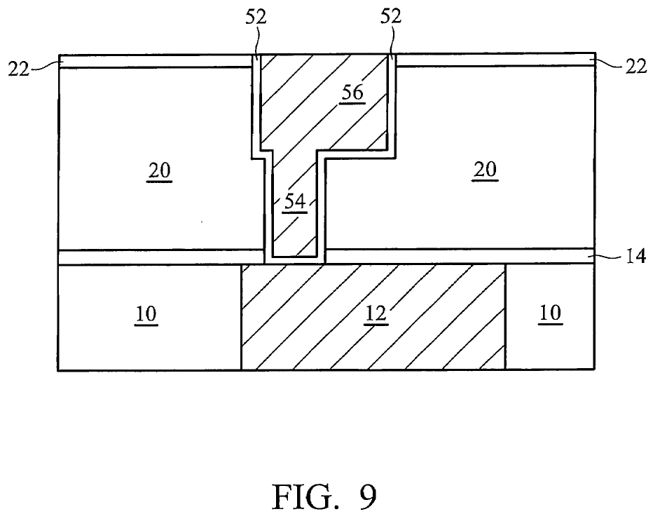

After the cleaning process, by-product layers 46, 48 and 50 are removed. FIG. 9 illustrates the formation of a barrier layer 52, a via 54 and a metal line 56. Barrier layer 52 preferably includes titanium, titanium nitride, tantalum, tantalum nitride, silicon carbide, silicon oxycarbide, and the like. Barrier layer 52 prevents the via material, particularly copper, from diffusing into low-k dielectric layer 20 and causing circuit failure. A conductive material, preferably a metallic material such as copper, tungsten, metal alloys, metal silicide, and metal nitrides, is filled into via opening 44 and trench opening 42. The excess material is then removed by using a chemical mechanical polish (CMP) process, leaving metal line 56 and via 54. MHM 24 is also preferably removed by the CMP process, or may be removed by an etching process following the CMP process.

The cleaning solution provided by the preferred embodiments of the present invention can remove organic and inorganic by-products simultaneously. Therefore, it can be used in other semiconductor formation processes in which organic and/or inorganic by-products are generated. The applicable processes include, but are not limited to, dual damascene processes, single damascene processes, and/or any other processes in which carbon-containing low-k dielectric materials are etched by dry etching.

The preferred embodiments of the present invention have several advantageous features. Only one process step is needed to remove organic and inorganic by-products, thus the cleaning process is significantly simplified. Experiment results have also shown the yield of the interconnect structures is significantly improved. In addition, parasitic capacitance of the interconnect structures remains low.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor wafer cleaning solution comprising:
an organic solvent;
a metal reagent;
a substitutive agent; and
water.

2. The cleaning solution of claim 1, wherein the organic solvent has a weight percentage of between about 0.01% and about 90%, the metal reagent has a weight percentage of between about 0.01% and about 30%, the substitutive agent has a weight percentage of between about 0.01% and about 30%, and the water has a weight percentage of between about 0.01% and about 70%.

3. The cleaning solution of claim 1, wherein the organic solvent has a weight percentage of between about 50% and about 80%.

4. The cleaning solution of claim 1, wherein the metal reagent has a weight percentage of between about 0.01% and about 10%.

5. The cleaning solution of claim 1, wherein the substitutive agent has a weight percentage of between about 0.01% and about 10%.

6. The cleaning solution of claim 1, wherein the organic solvent comprises a material selected from the group consisting essentially of propylene glycol monomethyl ether, ethylene glycol, 1,4-butynediol, butyrolactone, diethylene glycol monoethyl ether, diethylene glycol monobutyl ether, diethylene glycol monohexyl ether, N,N-dimethyl acetamide, N-methyl-2-pyrrolidone, cyclopentanone, dimethylsulfoxide, and combinations thereof.

7. The cleaning solution of claim 1, wherein the metal reagent comprises a material selected from the group consisting essentially of oxalic acid, malonic acid, citric acid, lactic acid, glycolic acid, propionic acid, Benzotriazole, 1,2,4-1H-Triazole, 7-Methylindole-2-carboxylic acid, Thioglycerol, 1-pyrroline-5-carboxylate, Tetramethylammonium fluoride, 1,2-ethanedicarboxylic acid, Glyoxylic Acid, 1,2-ethanedicarboxylic acid, and combinations thereof.

8. The cleaning solution of claim 1, wherein the substitutive agent comprises a material selected from the group consisting essentially of tetramethyl ammonium hydroxide, tetraethylammonium hydroxide, tetra-n-butylammonium hydroxide, 3-Aminopropanoic acid, 4-Aminobutyric acid, 6-Aminohexanoic acid, 5-Aminovaleric acid, and combinations thereof.

9. A method for cleaning a semiconductor wafer, the method comprising submerging the semiconductor wafer in a cleaning solution, wherein the cleaning solution comprises:
an organic solvent;
a metal reagent;
a substitutive agent; and
water.

10. The method of claim 9 further comprising:
dry etching a low-k dielectric material on the semiconductor wafer to form an opening; and
filling the opening with a conductive material, wherein the step of cleaning the semiconductor wafer is performed between the step of dry etching and the step of filling the opening.

11. The method of claim 9, wherein the semiconductor wafer is submerged in the cleaning solution for less than about 8 minutes.

12. The method of claim 9, wherein the cleaning solution has a temperature of between about 20° C. and about 70° C.

13. The method of claim 9, wherein the organic solvent has a weight percentage of between about 0.01% and about 90%, the metal reagent has a weight percentage of between about 0.01% and about 30%, the substitutive agent has a weight percentage of between about 0.01% and about 30%, and the water has a weight percentage of between about 0.01% and about 70%.

14. The method of claim 9, wherein the organic solvent has a weight percentage of between about 50% and about 80%.

15. The method of claim 9, wherein the metal reagent has a weight percentage of between about 0.01% and about 10%.

16. The method of claim 9, wherein the substitutive agent has a weight percentage of between about 0.01% and about 10%.

17. The method of claim 9, wherein the organic solvent comprises a material selected from the group consisting essentially of propylene glycol monomethyl ether, ethylene glycol, 1,4-butynediol, butyrolactone, diethylene glycol monoethyl ether, diethylene glycol monobutyl ether, diethylene glycol monohexyl ether, N,N-dimethyl acetamide, N-methyl-2-pyrrolidone, cyclopentanone, dimethylsulfoxide, and combinations thereof.

18. The method of claim 9, wherein the metal reagent comprises a material selected from the group consisting essentially of oxalic acid, malonic acid, citric acid, lactic acid, glycolic acid, propionic acid, Benzotriazole, 1,2,4-1H-Triazole, 7-Methylindole-2-carboxylic acid, Thioglycerol, 1-pyrroline-5-carboxylate, Tetramethylammonium fluoride, 1,2-ethanedicarboxylic acid, Glyoxylic Acid, 1,2-ethanedicarboxylic acid, and combinations thereof.

19. The method of claim 9, wherein the substitutive agent comprises a material selected from the group consisting essentially of tetramethyl ammonium hydroxide, tetraethylammonium hydroxide, tetra-n-butylammonium hydroxide, 3-Aminopropanoic acid, 4-Aminobutyric acid, 6-Aminohexanoic acid, 5-Aminovaleric acid, and combinations thereof.

20. A method of forming an interconnect structure of an integrated circuit, the method comprising:
forming a low-k dielectric layer over a substrate;
forming a metal hard mask over the low-k dielectric layer;
patterning the metal hard mask to form a first opening in the metal hard mask, wherein the low-k dielectric layer is exposed through the first opening;
etching the low-k dielectric layer through the first opening to form a second opening in the low-k dielectric layer;
performing a cleaning step by submerging the substrate and overlying structures in a cleaning solution, wherein the cleaning solution comprises:
an organic solvent;
a metal reagent;
a substitutive agent; and
water;
forming a diffusion barrier layer in the second opening; and
filling the second opening with a conductive material.

21. The method of claim 20 further comprising forming a metal feature in a dielectric layer before the step of forming the low-k dielectric layer, wherein the metal feature is exposed through the second opening after the step of etching the low-k dielectric layer.

22. The method of claim 20, wherein the step of etching the low-k dielectric layer comprises plasma etching.

23. The method of claim 20, wherein the organic solvent has a weight percentage of between about 0.01% and about 90%, the metal reagent has a weight percentage of between about 0.01% and about 30%, the substitutive agent has a weight percentage of between about 0.01% and about 30%, and the water has a weight percentage of between about 0.01% and about 70%.

24. The method of claim 20, wherein the semiconductor wafer is submerged in the cleaning solution for less than about 8 minutes.

25. The method of claim 20, wherein the cleaning solution has a temperature of between about 20° C. and about 70° C.

26. The method of claim 20, wherein the step of etching the low-k dielectric layer comprises:
partially etching the low-k dielectric layer through an opening in a photo resist over the metal hard mask;
ashing the photo resist; and
etching the low-k dielectric layer using the metal hard mask as a mask, so that the second opening comprises a trench opening and a via opening, wherein the via opening reaches a bottom of the low-k dielectric layer.
